(19) United States
(12) Patent Application Publication
(10) Pub. No.: US 2010/0155111 A1
(43) Pub. Date: Jun. 24, 2010

(54) MOUNTING STRUCTURE

(75) Inventor: Masahiro ONO, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/639,474

(22) Filed: Dec. 16, 2009

(30) Foreign Application Priority Data
Dec. 19, 2008 (JP) 2008-323029
Nov. 16, 2009 (JP) 2009-260547

(51) Int. Cl. H05K 1/16; H05K 1/03

(52) U.S. Cl. 174/255; 174/260

(57) ABSTRACT

A mounting structure of the present invention includes: electronic components, a first substrate on which the electronic components are mounted, a first resin for molding at least a part of a surface of the first substrate with the electronic components mounted on the surface, a second substrate on which the first substrate is mounted, connecting members for connecting the first substrate and the second substrate, and a flat reinforcing member disposed on the opposite surface of the second substrate from a surface on which the first substrate is mounted. The reinforcing member is disposed such that the longitudinal direction of the reinforcing member is arranged along the longitudinal direction of the first substrate.

The disclosure of Japanese Patent Application No. 2008-323029 filed Dec. 19, 2008 and Japanese Patent Application No. 2009-260547 filed Nov. 16, 2009 including specification, drawings and claims is incorporated herein by reference in its entirety.

### FIELD OF THE INVENTION

The present invention relates to a mounting structure having mounted components molded with resin and the like.

### BACKGROUND OF THE INVENTION

As a mounting structure of the prior art in which mounted components on a board are molded with resin and the like, an IC package reinforcing structure is disclosed in, for example, Japanese Patent No. 3241669. In the IC package reinforcing structure, an IC package on a substrate is surrounded by an enclosure-type reinforcing frame and the inside of the reinforcing frame having the IC package contained therein is molded with resin.

FIG. 9 is a sectional view showing the IC package reinforcing structure disclosed in Japanese Patent No. 3241669. The reinforcing structure reinforces a BGA IC package 21.

The BGA IC package 21 includes a substrate 22, an IC chip 23 mounted on the top surface of the substrate 22, and a plurality of solder balls 24 welded to the undersurface of the substrate 22. The solder balls 24 are arranged in a matrix on the undersurface of the substrate 22.

The IC chip 23 has electrode pads (not shown) connected to the electrode pads of the substrate 22 via bonding wires. In other words, the IC chip 23 is electrically connected to a wiring pattern on the substrate 22 via the bonding wires. The IC chip 23 and the bonding wires are molded with mold resin 25.

The foregoing BGA IC package 21 is mounted on a motherboard 26, and a reinforcing frame 27 for fixing the BGA IC package 21 to the motherboard 26 in an undetachable manner is fixed on the motherboard 26. The reinforcing frame 27 is an enclosure having thin side pieces 27a surrounding the outer periphery of the BGA IC package and a thin top piece 27b disposed above the BGA IC package.

The inside of the enclosure-type reinforcing frame 27 is molded with thermosetting resin 28. The thermosetting resin 28 is injected into the reinforcing frame 27 from notches formed on the reinforcing frame 27. Notches 29 are formed on the top piece 27b of the reinforcing frame 27. Notches (not shown) are formed also on the side pieces 27a of the reinforcing frame 27.

### DISCLOSURE OF THE INVENTION

As has been discussed, an object to be reinforced by the IC package reinforcing structure of the prior art is limited to the IC package, so that mounted components other than the IC package on the substrate are not reinforced. Hence the mounted components other than the IC package may fall off the substrate or may be cracked by an external cause (external force) such as falling.

Further, in the IC package reinforcing structure of the prior art, it is not possible to sufficiently address warping of the substrate on which the IC package is mounted. Warping is likely to occur due to a reduction in the thickness of the mounting structure. Mounting structures have been reduced in thickness in response to needs for smaller and lighter equipment. Particularly, mobile equipment such as a cellular phone has been reduced in size and weight.

On the substrate on which the IC package is mounted, warping may occur during a strength test such as a drop test on equipment. Additionally, the thermosetting resin charged into the reinforcing frame has a different thermal expansion coefficient from a material composing the IC package, a material of the substrate on which the IC package is mounted, and a material of the reinforcing frame, so that the substrate on which the IC package is mounted may be warped when the thermosetting resin is injected or the injected thermosetting resin is cured.

In case of warping on the substrate on which the IC package is mounted, a stress is applied to joints between the substrate and the solder balls of the IC package or joints between the undersurface of the IC package and the solder balls, so that the solder balls may fall off the IC package or the substrate on which the IC package is mounted. Moreover, the IC package may be cracked by the stress.

Hence, only with the IC package reinforcing structure of the prior art for reinforcing a mounting structure, the strength characteristics and reliability of a product are disadvantageously reduced particularly in equipment such as mobile equipment having been reduced in size and weight.

An object of the present invention is to provide a mounting structure which can solve the problems of the prior art. To be specific, an object of the present invention is to provide a mounting structure which can reinforce mounted components to reliably protect the mounted components from an external force and suppress distortion on the substrate to reduce a stress applied to the mounted components on the substrate, thereby achieving a product with high strength and reliability while obtaining a small thickness.

In order to attain the object, a mounting structure of the present invention includes: electronic components; a first substrate on which the electronic components are mounted; a first resin for molding at least a part of a surface of the first substrate with the electronic components mounted on the surface; a second substrate on which the first substrate is mounted; connecting members for connecting the first substrate and the second substrate; and a flat reinforcing member disposed on the opposite surface of the second substrate from a surface on which the first substrate is mounted. Further, the reinforcing member is disposed such that the longitudinal direction of the reinforcing member is arranged along the longitudinal direction of the first substrate.

Further, the reinforcing member is preferably made of a second resin having a thermal expansion coefficient equal to or close to the thermal expansion coefficient of the first resin.

Moreover, the first resin preferably molds the overall surface of the first substrate with the electronic components mounted on the surface.

The mounting structure of the present invention may further include a frame disposed so as to surround the outer periphery of the first substrate, on the surface of the second substrate with the first substrate mounted on the surface. When the frame is disposed thus on the second substrate, it is preferable that the inside of the frame is partially or entirely molded with the first resin.

The mounting structure of the present invention may further include an enclosure disposed so as to surround the first substrate on the surface of the second substrate with the first substrate mounted on the surface. The enclosure has a mesh surface opposed to the surface of the first substrate with the electronic components mounted on the surface. When the enclosure having a mesh part is disposed on the second substrate, it is preferable that the inside of the enclosure is partially or entirely molded with the first resin.

Further, the plurality of connecting members may be arranged along the outer periphery of the first substrate. When the plurality of connecting members are disposed thus between the first substrate and the second substrate, the electronic components may be mounted on both surfaces of the first substrate. Preferably, the first resin is disposed at least between the first substrate and the second substrate to partially or entirely mold a space surrounded by the plurality of connecting members.

According to the present invention, it is possible to sufficiently reinforce the mounted components on the substrate by resin molding and suppress distortion on the substrate by the reinforcing member disposed on the second substrate, thereby reliably obtaining a sufficient reinforcing structure against an external force.

Thus it is possible to sufficiently reinforce the mounted components on the substrate to reliably protect the mounted components from an external force and suppress distortion, which is caused by falling and the like, on the substrate to reduce a stress applied to the mounted components on the substrate, thereby achieving a product with high strength and reliability while obtaining a small thickness.

### BRIEF DESCRIPTION OF THE DRAWINGS

FIG. 1 is a sectional view schematically showing an example of a mounting structure according to a first embodiment of the present invention;

FIG. 2 is a perspective view schematically showing the example of the mounting structure taken from the back side according to the first embodiment of the present invention;

FIG. 3 is a perspective view schematically showing the example of the mounting structure taken from the front side according to the first embodiment of the present invention;

FIG. 4 is a sectional view schematically showing an example of a mounting structure according to a second embodiment of the present invention;

FIG. 5 is a sectional view schematically showing an example of a mounting structure according to a third embodiment of the present invention;

FIG. 6 is a perspective view schematically showing the example of the mounting structure taken from the front side according to the third embodiment of the present invention;

FIG. 7 is a sectional view schematically showing an example of a mounting structure according to a fourth embodiment of the present invention;

FIG. 8 is a partial sectional view schematically showing the example of the mounting structure according to the fourth embodiment of the present invention; and

FIG. 9 is a sectional view showing an IC package reinforcing structure of the prior art.

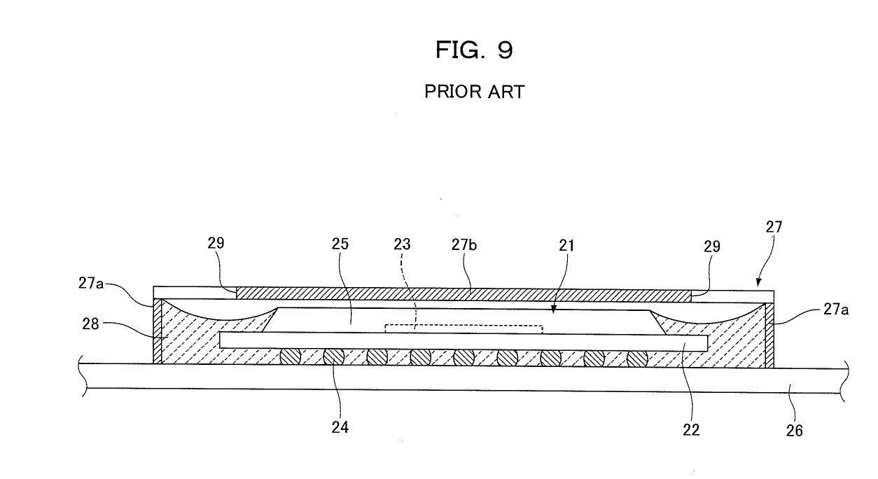

### DESCRIPTION OF THE EMBODIMENTS

### First Embodiment

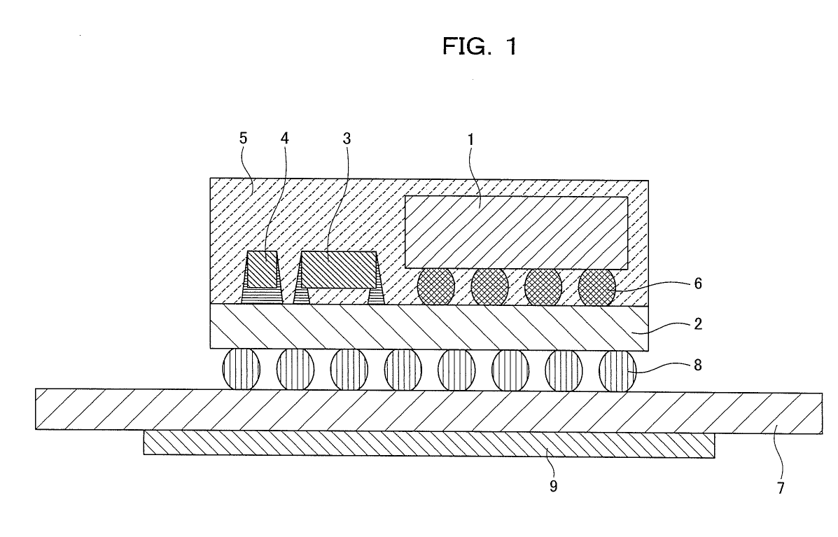

A mounting structure according to a first embodiment of the present invention will be specifically described below in accordance with the accompanying drawings. FIG. 1 is a sectional view schematically showing an example of the mounting structure according to the first embodiment of the present invention.

In the first embodiment, as shown in FIG. 1, an IC package 1 as an electronic component is mounted on one surface of a first circuit board 2. On the one surface of the first circuit board 2, electronic components 3 and 4 other than the IC package 1 are also mounted. Further, the one surface of the first circuit board 2 is molded with molding resin 5 serving as a first resin. On the opposite surface of the IC package 1 from the first circuit board 2, a plurality of solder balls 6 are welded. The solder balls 6 are arranged in a matrix on the opposite surface of the IC package 1 from the first circuit board 2. The first circuit board 2 has a thickness of about 0.5 mm when the first circuit board 2 is, for example, an eight-layer board.

In this configuration, the IC package 1 and the first circuit board 2 are electrically connected to each other via the solder balls 6. The electronic components 3 and 4 and the first circuit board 2 are electrically connected to each other via solder. A pattern of electrical connection between the electronic components and the first circuit board 2 is not limited to the foregoing pattern of connection. For example, the IC package 1 and the first circuit board 2 may be electrically connected via bonding wires.

The molding resin 5 molds the overall surface of the first circuit board 2 with the electronic components mounted on the surface. Thus the IC package 1 and the electronic components 3 and 4 on the first circuit board 2 are covered and molded with the molding resin 5. For example, the molding resin 5 is about 2.0 mm or less in height.

In the following explanation, the molding resin 5 molds the overall surface of the first circuit board 2 with the electronic components mounted on the surface. The molding resin 5 may partially mold the surface of the first circuit board 2 with the electronic components mounted on the surface. For example, the molding resin 5 may cover some of the plurality of electronic components on the first circuit board 2.

The plurality of electronic components are mounted on the first circuit board 2, the surface having the electronic components mounted thereon is molded with the molding resin 5 together with the electronic components, and then the first circuit board 2 is mounted on a second circuit board 7. For example, when the second circuit board 7 has eight to ten layers, the second circuit board 7 has a thickness of about 0.5 mm to 1.0 mm.

The first circuit board 2 and the second circuit board 7 are connected to each other via a plurality of connecting members 8. By the connecting members 8, the first circuit board 2 and the second circuit board 7 are electrically connected to each other. The connecting members 8 may be, for example, solder balls and the like.

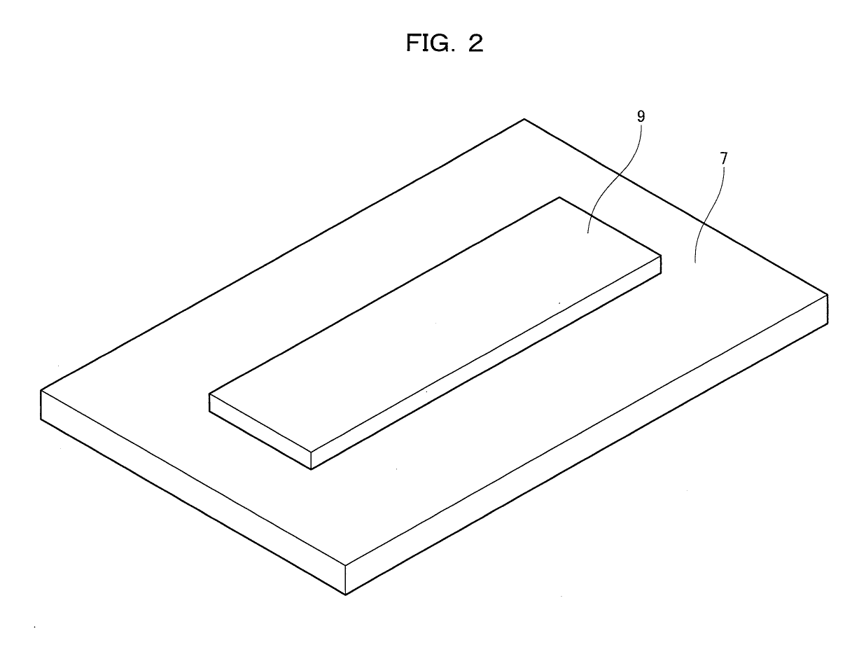

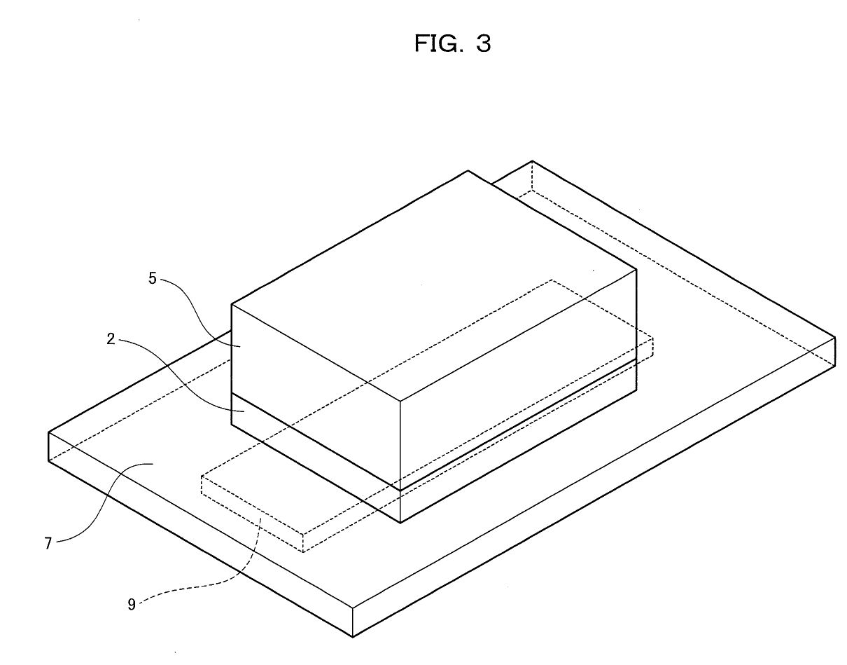

On the opposite surface of the second circuit board 7 from a surface on which the first circuit board 2 is mounted, a reinforcing member 9 is disposed. FIG. 2 is a perspective view schematically showing the example of the mounting structure taken from the back side according to the first embodiment of the present invention. FIG. 3 is a perspective view schematically showing the example of the mounting structure taken from the front side according to the first embodiment of the present invention. In this case, the back side is a surface side where the reinforcing member 9 is disposed on the second circuit board 7 and the front side is a surface side where the first circuit board 2 is mounted on the second circuit board 7.

As shown in FIGS. 2 and 3, the reinforcing member 9 is flat and the longitudinal direction of the reinforcing member 9 is disposed along the longitudinal direction of the first circuit board 2. The reinforcing member 9 disposed thus can suppress distortion on the first circuit board 2 even when equipment falls.

The reinforcing member 9 may have any desired size. Assuming that the first circuit board 2 is projected to the surface of the second circuit board 7 with the reinforcing member 9 disposed on the surface, distortion on the first circuit board 2 can be further suppressed by disposing the reinforcing member 9 so as to cover a part of a region where the first circuit board 2 is projected (that is, such that a region where the first circuit board 2 is projected overlaps a region where the reinforcing member 9 is disposed).

The following will specifically describe the molding resin 5. The molding resin 5 may be any one of a thermosetting resin and a thermoplastic resin. To be specific, the molding resin 5 can be selected from silicone resin, acrylic resin, ABS resin, polypropylene, polyethylene, polystyrene, polyamide, polycarbonate, polyphthalamide, a liquid crystal polymer, fluorocarbon resin, urethane resin, elastomer, melamine, phenol, epoxy resin, and so on.

For example, the molding resin 5 may be molded using a mold or may be formed using one of a dispenser and potting. Alternatively, after gaps between the first circuit board 2 and the electronic components are molded with resin by using a dispenser, the surface of the first circuit board 2 with the electronic components mounted on the surface may be molded with resin by using a mold. Alternatively, the molding resin 5 may be formed by printing. When the molding resin 5 is formed by printing, printing is preferably performed along with evacuation. With printing and evacuation, the gaps between the first circuit board 2 and the electronic components can be satisfactorily molded with resin. A dispenser, potting, and evacuation may be used in combination.

As shown in FIG. 1, there is a clearance between the first circuit board 2 and the second circuit board 7. The clearance may be molded with resin, achieving more desirable reinforcement. It is desirable that the resin for molding the clearance between the first circuit board 2 and the second circuit board 7 has a thermal expansion coefficient equal to or close to the thermal expansion coefficient of the molding resin 5. Thus distortion in the molding structure can be suppressed as compared with the case where the resins have different thermal expansion coefficients.

The reinforcing member 9 will be specifically described below. The reinforcing member 9 may be a resin plate. Alternatively, the reinforcing member 9 may be formed using a resin coating. A resin used as a material of the reinforcing member 9 (second resin) may be any one of a thermosetting resin and a thermoplastic resin. To be specific, like the molding resin 5, the material of the reinforcing member 9 can be selected from silicone resin, acrylic resin, ABS resin, polypropylene, polyethylene, polystyrene, polyamide, polycarbonate, polyphthalamide, a liquid crystal polymer, fluorocarbon resin, urethane resin, elastomer, melamine, phenol, epoxy resin, and so on.

The material of the reinforcing member 9 is a resin having a thermal expansion coefficient equal to or close to the thermal expansion coefficient of the molding resin 5. Thus distortion in the molding structure can be suppressed as compared with the case where the molding resin 5 and the reinforcing member 9 have different thermal expansion coefficients.

Although the reinforcing member 9 may have a desired thickness, it is desirable to maximize the thickness of the reinforcing member 9 because a large thickness can obtain high flexural rigidity. To be specific, it is desirable that the reinforcing member 9 is so thick as to have a modulus of elasticity of at least 1 GPa at room temperature (at about 25° C.). For example, when the reinforcing member 9 is made of epoxy resin, the reinforcing member 9 desirably has a thickness of about 0.1 mm to 0.5 mm.

According to the first embodiment, it is possible to reinforce not only the IC package but also other electronic components with molding resin and suppress distortion on the substrate with the reinforcing member, thereby achieving a mounting structure with high reliability.

### Second Embodiment

A mounting structure according to a second embodiment of the present invention will be specifically described below with reference to the accompanying drawings. In the following explanation, different points from the first embodiment will be mainly described. Elements corresponding to the elements of the first embodiment will be indicated by the same reference numerals and the explanation thereof is omitted when necessary.

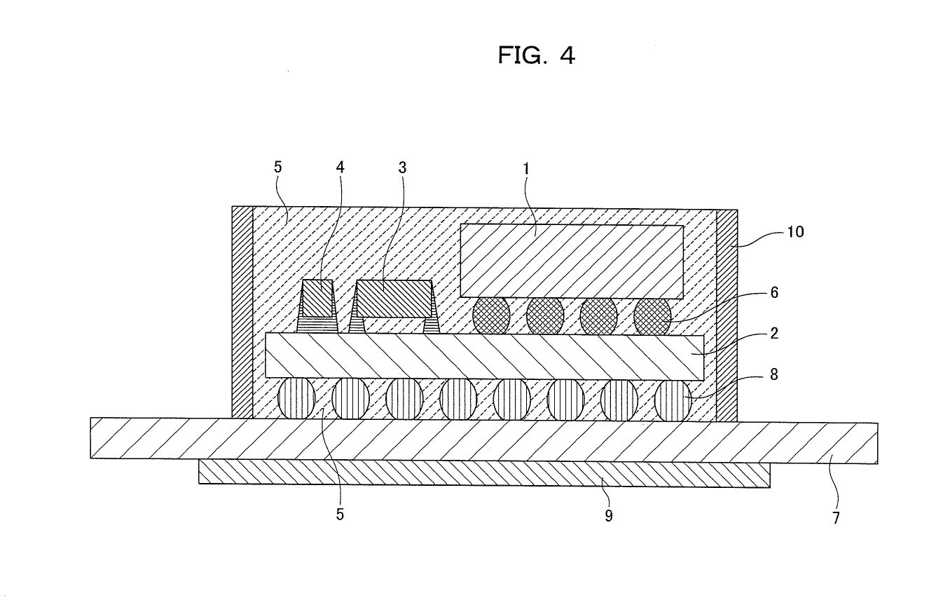

FIG. 4 is a sectional view schematically showing an example of the mounting structure according to the second embodiment of the present invention. The mounting structure of the second embodiment is different from the first embodiment in that a frame (dam) 10 is provided as shown in FIG. 4.

The frame 10 is disposed on a surface of a second circuit board 7 so as to surround the outer periphery of a first circuit board 2 mounted on the surface. For example, the frame 10 is about 2.0 mm in height. Further, the frame 10 has a thickness of, for example, about 0.8 mm to 1.0 mm.

Molding resin 5 is charged inside the frame 10. Thus an IC package 1, an electronic component 3, and an electronic component 4 on the first circuit board 2 are covered and molded with the molding resin 5. Further, a clearance between the first circuit board 2 and the second circuit board 7 is also molded with the molding resin 5, achieving more desirable reinforcement.

When the molding resin 5 is charged thus inside the frame 10, the thermal expansion coefficient of resin for molding a surface of the first circuit board 2 with the electronic components mounted on the surface is equal to the thermal expansion coefficient of resin for molding the clearance between the first circuit board 2 and the second circuit board 7. Thus distortion in the mounting structure can be suppressed as compared with the case where the resins have different thermal expansion coefficients.

The present invention is not limited to the case where the molding resin 5 is charged inside the frame 10. The molding resin 5 may mold a part of the surface of the first circuit board 2 with the electronic components mounted on the surface and a part of the clearance between the first circuit board 2 and the second circuit board 7. For example, the molding resin 5 may cover some of the plurality of electronic components on the first circuit board 2.

The frame 10 will be specifically described below. The material of the frame 10 is not particularly limited but a resin is preferably used in view of the weight reduction and cost of equipment. The resin may be any one of a thermosetting resin and a thermoplastic resin. To be specific, the resin can be selected from silicone resin, acrylic resin, ABS resin, polypropylene, polyethylene, polystyrene, polyamide, polycarbonate, polyphthalamide, a liquid crystal polymer, fluorocarbon resin, urethane resin, elastomer, melamine, phenol, epoxy resin, and so on. In order to suppress distortion in the mounting structure, it is desirable to use a resin having a thermal expansion coefficient equal to or close to the thermal expansion coefficient of the molding resin 5.

For example, the frame 10 made of resin may be formed on the second circuit board 7 by printing or using a dispenser. Alternatively, for example, the frame 10 made of resin may be molded using a mold, and then the molded frame 10 may be bonded to the second circuit board 7 with adhesive.

The molding resin 5 is charged into the frame 10 through the open top of the frame 10 after the first circuit board 2 having the plurality of electronic components mounted thereon is mounted on the second circuit board 7 and the frame 10 is formed.

For example, the molding resin 5 may be molded using a mold or may be formed using one of a dispenser and potting. Alternatively, after gaps between the first circuit board 2 and the electronic components are molded with resin by using a dispenser, the molding resin 5 may be molded using a mold. Alternatively, the molding resin 5 may be formed by printing. When the molding resin 5 is formed by printing, printing is preferably performed along with evacuation. With printing and evacuation, it is possible to satisfactorily mold with resin the gaps between the first circuit board 2 and the electronic components and the clearance between the first circuit board 2 and the second circuit board 7. A dispenser, potting, and evacuation may be used in combination.

In the second embodiment, as shown in FIG. 4, there is a gap between the first circuit board 2 and the frame 10 and the molding resin 5 is charged through this gap into the clearance between the first circuit board 2 and the second circuit board 7.

However, the passage of the molding resin 5 into the clearance between the first circuit board 2 and the second circuit board 7 is not limited to the passage through the gap between the first circuit board 2 and the frame 10. For example, the molding resin 5 may be charged through a through hole formed beforehand on the first circuit board 2. Thus when the through hole on the first circuit board 2 is used, the frame 10 may be in contact with the sides of the first circuit board 2.

According to the second embodiment, it is possible to reinforce not only the IC package but also other electronic components with the molding resin and suppress distortion on the substrate with a reinforcing member, thereby achieving a mounting structure with high reliability.

### Third Embodiment

A mounting structure according to a third embodiment of the present invention will be specifically described below with reference to the accompanying drawings. In the following explanation, different points from the first and second embodiments will be mainly described. Elements corresponding to the elements of the first and second embodiments will be indicated by the same reference numerals and the explanation thereof is omitted when necessary.

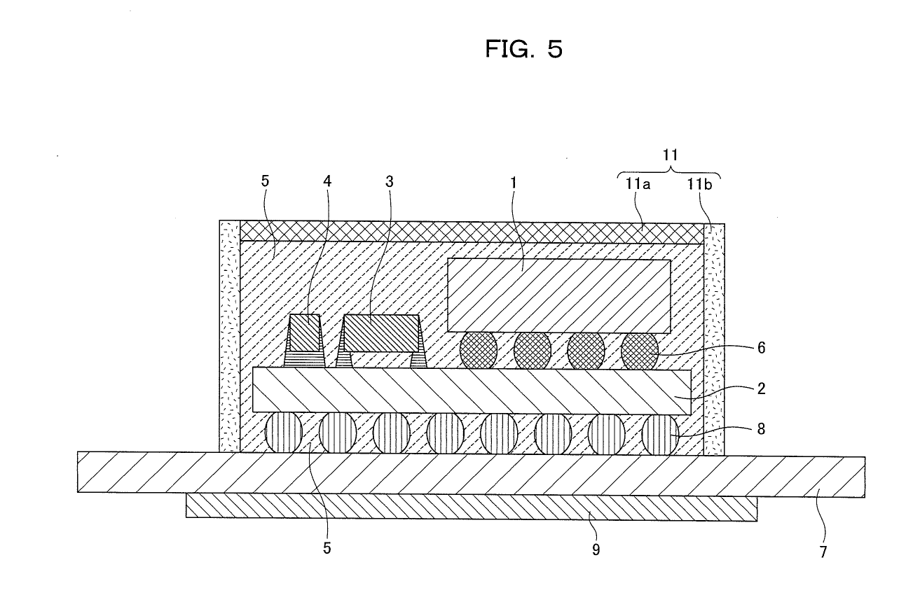

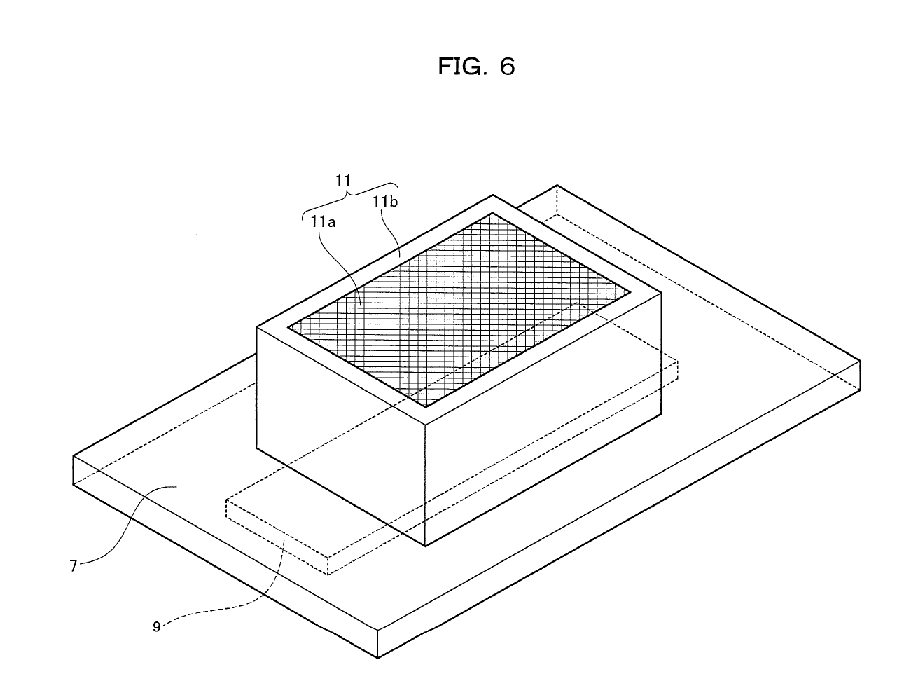

FIG. 5 is a sectional view schematically showing an example of the mounting structure according to the third embodiment of the present invention. FIG. 6 is a perspective view schematically showing the example of the mounting structure taken from the front side according to the third embodiment of the present invention. In this case, the front side is a surface side where a first circuit board 2 is mounted on a second circuit board 7. The mounting structure of the third embodiment is different from the first and second embodiments in that a shield frame 11 is provided as an enclosure as shown in FIGS. 5 and 6.

The shield frame 11 is disposed on a surface of the second circuit board 7 with the first circuit board 2 mounted on the surface such that the shield frame 11 surrounds the first circuit board 2 and an IC package 1, an electronic component 3, and an electronic component 4 on the first circuit board 2.

Moreover, the shield frame 11 has a mesh surface opposed to a surface of the first circuit board 2 with the electronic components mounted on the surface (hereinafter, the mesh surface will be referred to as a ceiling part 11a of the shield frame 11). In the shield frame 11, the ceiling part 11a and a side wall 11b may be separated parts or an integrated part.

The shield frame 11 is, for example, about 2.0 mm in height. Further, the side wall lib of the shield frame 11 is, for example, about 0.08 mm to 0.2 mm in thickness. The material of the shield frame 11 can be selected from, for example, german silver, SUS, phosphor bronze, and so on.

The shield frame 11 having the mesh-like ceiling part is disposed thus on the second circuit board 7, and the inside of the shield frame 11 is filled with molding resin 5.

The molding resin 5 is charged into the shield frame 11 through the mesh-like ceiling part 11a of the shield frame 11 after the shield frame 11 is mounted on the second circuit board 7 with the first circuit board 2 on which the plurality of electronic components are mounted. The shield frame 11 is mounted on the first circuit board 2 after being sucked and positioned by a nozzle in a similar manner to the electronic components.

In this way, the molding resin 5 enters the inside of the shield frame 11 through the mesh-like ceiling part 11a. When the resin is charged into the shield frame 11 from above of the ceiling part 11a, an opening of the mesh has to be large enough to allow the passage of the resin. For example, it is desirable that the area of the opening is at least 1.0 mm×1.0 mm. Alternatively, the end of the nozzle for injecting the resin may be inserted into the opening of the mesh to charge the resin into the shield frame. In this case, the opening of the mesh only has to be larger than the diameter of the end of the nozzle. Moreover, the way to charge the molding resin 5 is similar to that of the second embodiment. A mold, a dispenser, potting, and so on may be used or a printing method may be used.

According to the third embodiment, it is possible to reinforce not only the IC package but also other electronic components with the molding resin and suppress distortion on the substrate with a reinforcing member, thereby achieving a mounting structure with high reliability.

### Fourth Embodiment

A mounting structure according to a fourth embodiment of the present invention will be specifically described below with reference to the accompanying drawings. In the following explanation, different points from the first to third embodiments will be mainly described. Elements corresponding to the elements of the first to third embodiments will be indicated by the same reference numerals and the explanation thereof is omitted when necessary.

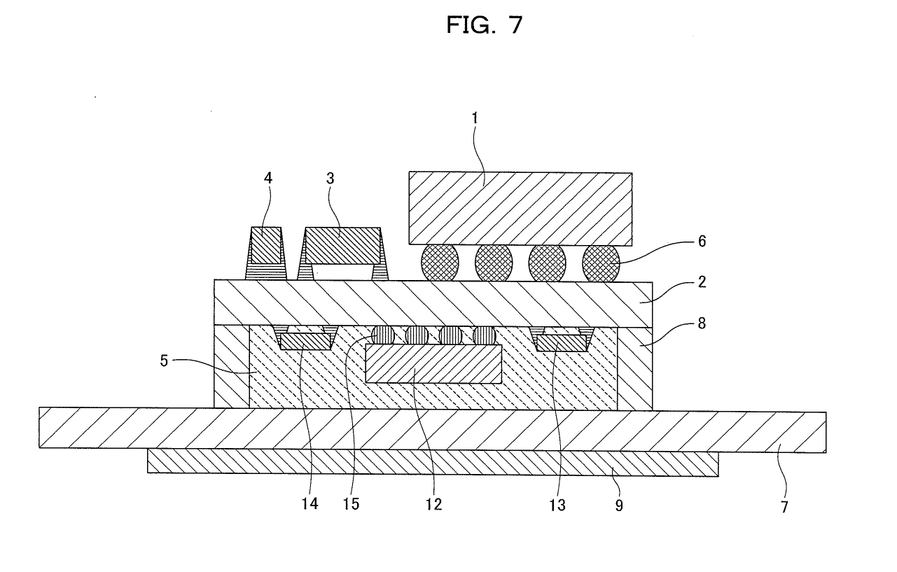

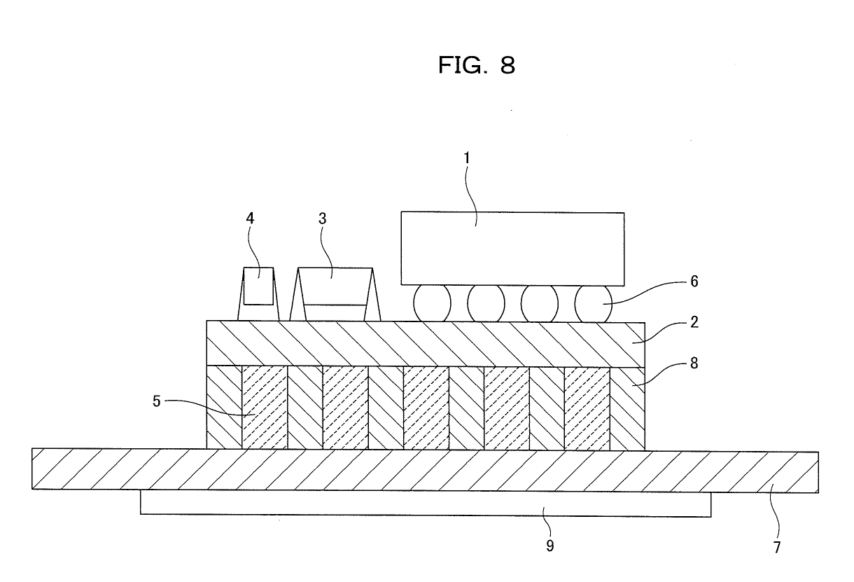

FIG. 7 is a sectional view schematically showing an example of the mounting structure according to the fourth embodiment of the present invention. FIG. 8 is a partial sectional view schematically showing the example of the mounting structure according to the fourth embodiment of the present invention. The mounting structure of the fourth embodiment is different from the first to third embodiments in that a plurality of connecting members 8 are provided along the outer periphery of a first circuit board 2 as shown in FIGS. 7 and 8.

Further, in the fourth embodiment, an IC package 1, an electronic component 3, and an electronic component 4 are mounted on one surface of the first circuit board 2 and an IC package 12 acting as an electronic component is mounted on the other surface of the first circuit board 2, that is, on the other surface of the first circuit board 2 with the connecting members 8 connected to the other surface. Further, on the other surface of the first circuit board 2, electronic components 13 and 14 are mounted in addition to the IC package 12.

In this configuration, the IC package 12 and the first circuit board 2 are electrically connected to each other via solder balls 15. Moreover, the electronic components 13 and 14 and the first circuit board 2 are electrically connected to each other via solder. As has been discussed in the first embodiment, the pattern of an electrical connection between the electronic components and the first circuit board 2 is not limited to the foregoing pattern of connection.

Further, in the fourth embodiment, molding resin 5 is charged into a space surrounded by the plurality of connecting members 8. Hence, the IC package 12, the electronic component 13, and the electronic component 14 mounted on the other surface of the first circuit board 2 are covered and molded with the molding resin 5. However, the molding resin 5 is not always charged into the space surrounded by the plurality of connecting members 8 and the molding resin 5 may mold a part of the space surrounded by the plurality of connecting members 8.

In this configuration, the one surface of the first circuit board 2 where the IC package 1, the electronic component 3, and the electronic component 4 are mounted is not molded with resin. As a matter of course, the one surface of the first circuit board 2 may be molded with resin as has been discussed in the first embodiment. When the one surface of the first circuit board 2 is molded with resin, it is desirable to use a resin having a thermal expansion coefficient equal to or close to the thermal expansion coefficient of a resin for molding the space surrounded by the plurality of connecting members 8, in order to suppress distortion in the mounting structure.

After the first circuit board 2 having the plurality of electronic components mounted thereon is mounted on the second circuit board 7, the molding resin 5 is charged through a gap between the adjacent connecting members 8 into the space surrounded by the plurality of connecting members 8.

For example, the molding resin 5 may be molded using a mold or may be formed using a dispenser. A dispenser and evacuation may be used in combination. When the resin is charged from the outside of the connecting members 8, the gap between the adjacent connecting members has to be large enough to allow the passage of the resin. For example, it is desirable that the width of the gap is at least 1.0 mm. Alternatively, the end of a nozzle for injecting the resin may be inserted into the gap between the adjacent connecting members to charge the resin. In this case, the width of the gap between the adjacent connecting members only has to be larger than the diameter of the end of the nozzle.

The connecting members 8 may be, for example, solder balls, Cu post electrodes, and so on. Furthermore, the connecting members 8 may be members having wiring electrodes formed on a surface of a resin molded article. A material for connecting the connecting members 8 to the circuit board may be solder, conductive resin paste, and so on. Alternatively, the connecting members 8 may be connected to the circuit board by a heat sealing method and the like for electrodes.

The heights of the connecting members 8 are determined according to the heights of the IC package 12 and the electronic components 13 and 14 which are mounted on the other surface of the first circuit board 2. For example, the connecting members 8 are about 0.5 mm to 1.0 mm in height.

According to the fourth embodiment, it is possible to reinforce not only the IC package but also other electronic components with the molding resin and suppress distortion on the substrate with a reinforcing member, thereby achieving a mounting structure with high reliability.

According to the mounting structure of the present invention, it is possible to reinforce the mounted components on the substrate, reliably protect the mounted components from an external force, and suppress distortion on the substrate to reduce a stress applied to the mounted components on the substrate, thereby achieving a product with high strength and reliability while obtaining a small thickness. Thus the mounting structure of the present invention is also applicable to modules of mobile equipment and so on.

The foregoing explanation described some exemplary embodiments in detail according to the present invention. It will be easily understood by those skilled in the art that various changes can be made in the exemplary embodiments without substantially departing from the new teachings of the present invention and the advantage of the present invention. Thus these various changes are intended to be included in the scope of the present invention.

What is claimed is:

1. A mounting structure comprising:
electronic components;
a first substrate on which the electronic components are mounted;
a first resin for molding at least a part of a surface of the first substrate with the electronic components mounted on the surface;
a second substrate on which the first substrate is mounted;
connecting members for connecting the first substrate and the second substrate; and
a flat reinforcing member disposed on an opposite surface of the second substrate from a surface on which the first substrate is mounted,
wherein the reinforcing member is disposed such that a longitudinal direction of the reinforcing member is arranged along a longitudinal direction of the first substrate.

2. The mounting structure according to claim 1, wherein the reinforcing member is made of a second resin having a thermal expansion coefficient equal to or close to a thermal expansion coefficient of the first resin.

3. The mounting structure according to claim 1, wherein the first resin molds the overall surface of the first substrate with the electronic components mounted on the surface.

4. The mounting structure according to claim 1, further comprising a frame disposed so as to surround an outer periphery of the first substrate, on the surface of the second substrate with the first substrate mounted on the surface.

5. The mounting structure according to claim 4, wherein an inside of the frame is partially or entirely molded with the first resin.

6. The mounting structure according to claim 1, further comprising an enclosure disposed so as to surround the first substrate on the surface of the second substrate with the first substrate mounted on the surface,
wherein the enclosure has a mesh surface opposed to the surface of the first substrate with the electronic components mounted on the surface.

7. The mounting structure according to claim 6, wherein an inside of the enclosure is partially or entirely molded with the first resin.

8. The mounting structure according to claim 1, wherein the plurality of connecting members are arranged along an outer periphery of the first substrate.

9. The mounting structure according to claim 8, wherein the electronic components are mounted on both surfaces of the first substrate, and the first resin is disposed at least between the first substrate and the second substrate to partially or entirely mold a space surrounded by the plurality of connecting members.
